(19) United States
(12) Patent Application Publication
(10) Pub. No.: US 2013/0214285 A1
(43) Pub. Date: Aug. 22, 2013

(54) Semiconductor Component and Method for Producing a Semiconductor Component

(71) Applicants: Peter Stauss, Regensburg (DE); Joachim Hertkorn, Alteglofsheim (DE); Philipp Drechsel, Mintraching (DE)

(72) Inventors: Peter Stauss, Regensburg (DE); Joachim Hertkorn, Alteglofsheim (DE); Philipp Drechsel, Mintraching (DE)

(73) Assignee: OSRAM OPTO SEMICONDUCTORS GMBH, Regensburg (DE)

(21) Appl. No.: 13/819,219

(22) PCT Filed: Aug. 11, 2011
(86) PCT No.: PCT/EP2011/063883

§ 371 Date: Apr. 29, 2013

(30) Foreign Application Priority Data
Aug. 26, 2010 (DE) 10 2010 035 489.9

(51) Int. Cl. H01L 29/20

(52) U.S. Cl. CPC H01L 29/2003
USPC 257/76; 438/507

(57) ABSTRACT

A semiconductor component has a semiconductor layer sequence made of a nitridic composite semiconductor material on a substrate. The substrate includes a silicon surface facing the semiconductor layer sequence. The semiconductor layer sequence includes an active region and at least one intermediate layer made of an oxygen-doped AN composite semiconductor material between the substrate and the active region.

This patent application is a national phase filing under section 371 of PCT/EP2011/063883, filed Aug. 11, 2011, which claims the priority of German patent application 10 2010 035 489.9, filed Aug. 26, 2010, each of which is incorporated herein by reference in its entirety.

### TECHNICAL FIELD

A semiconductor component and a method for producing a semiconductor component are specified.

### BACKGROUND

Compound semiconductor materials, in particular so-called group III-V compound semiconductors, are of great importance, for example for the production of light-emitting diodes (LEDs). GaN-based LEDs, in particular, make it possible to generate light as far as the ultraviolet spectral range. In order to produce such LEDs, suitable layer sequences, for example, composed of GaN-containing compound semiconductor materials, are grown on a substrate. Substrate materials used for epitaxial growth usually include sapphire or silicon carbide, which have a lattice structure that is matched to the lattice structure of the compound semiconductor materials. However, the disadvantage of these substrate materials resides in their high price, for example.

A more favorable substrate material, which is used in many cases in semiconductor technology, is silicon. During the growth of, in particular, nitridic compound semiconductor materials on silicon substrates, however, strains occur on account of different lattice parameters of the materials involved, which lead to a reduction of the crystal quality of the grown layers.

### SUMMARY OF THE INVENTION

At least some embodiments specify a semiconductor component comprising a semiconductor layer sequence on a substrate. In addition, at least some embodiments specify a method for producing a semiconductor component.

A semiconductor component in accordance with one embodiment has, in particular, a semiconductor layer sequence composed of a nitridic compound semiconductor material applied on a substrate.

A method for producing a semiconductor component comprises, in accordance with one embodiment, in particular applying a semiconductor layer sequence composed of a nitridic compound semiconductor material on a substrate.

The following description of embodiments and features concerning the component and concerning the method for producing the component relates equally to the semiconductor component and also to the method for producing the semiconductor component.

Here and hereinafter, “based on a nitridic compound semiconductor material” or “composed of a nitridic compound semiconductor material” means that the semiconductor layer sequence is a layer sequence which is deposited epitaxially on the substrate and which has at least one layer composed of a nitride III-V compound semiconductor material, preferably AlₙGaₘIn₁₋ₘ₋ₙN, where 0≦n≦1, 0≦m≦1 and n+m≦1. In this case, this material need not necessarily have a mathematically exact composition according to the above formula. Rather, it can comprise one or more dopants and additional constituents which substantially do not change the characteristic physical properties of the AlₙGaₘIn₁₋ₘ₋ₙN material. For the sake of simplicity, however, the above formula only includes the essential constituents of the crystal lattice (Al, Ga, In, N), even if these can be replaced in part by small amounts of further substances.

In accordance with a further embodiment, the semiconductor layer sequence is grown on the substrate by means of an epitaxial growth method, particularly preferably by means of an MOVPE method or else by means of an MBE method.

In accordance with a further embodiment, the substrate has a silicon surface facing the semiconductor layer sequence. That means, in particular, that the semiconductor layer sequence is grown on the silicon surface of the substrate.

In accordance with a further embodiment, the substrate has a (111) plane at the silicon surface; that means that the silicon surface of the substrate is a (111) plane of a silicon crystal layer. A silicon surface having this orientation is distinguished by an increased upper yield point combined with other orientations. Furthermore, on account of its sixfold symmetry, a (111) plane is particularly suitable for the deposition of nitridic compound semiconductor materials.

The substrate can be embodied, in particular, as a silicon bulk substrate or as an SOI substrate (“silicon on insulator substrate”).

In accordance with a further embodiment, the semiconductor layer sequence has an active region, which provides the actual functionality of the semiconductor component. By way of example, the active region can have a layer sequence composed of p- and n-doped layers between which is arranged an active layer provided for generating and/or for receiving radiation. In this embodiment, the semiconductor component is embodied as an optoelectronic component. Alternatively or additionally, the semiconductor component can be embodied as a, preferably active, electronic semiconductor component, for example, as a transistor, for instance, as a high electron mobility transistor (HEMT) or as a hetero-junction bipolar transistor (HBT). In this case, too, the active region of the semiconductor layer sequence has suitable layers that determine the functionality of the semiconductor component.

Compared with other known silicon-based semiconductor components, in which the functional regions of the component are typically at least partly integrated into the silicon substrate, in the case of the semiconductor component described here the active region and thus the region determining the functionality is situated outside the substrate.

In accordance with a further embodiment, the semiconductor layer sequence has at least one intermediate layer composed of an oxygen-doped AN compound semiconductor material between the substrate and the active region. In particular, during the production of the semiconductor component, firstly the intermediate layer composed of the oxygen-doped AN compound semiconductor material is applied to the substrate having the silicon surface and then the active region of the semiconductor layer sequence is applied.

In accordance with a further embodiment, the oxygen-doped AN compound semiconductor material also comprises Ga and/or In in addition to Al and N as host crystal constituents. In particular, the AN compound semiconductor material can comprise AlGaN having a Ga proportion of less than or equal to 50%, preferably having a Ga proportion of less than or equal to 20%, and particularly preferably having a Ga proportion of less than or equal to 10%, in each case relative to the group III elements.

In accordance with a further embodiment, the oxygen-doped AN compound semiconductor material is Ga- and In-free and merely comprises Al and N as host crystal elements, apart from the doping. However, the terms “Ga-free” and “In-free” also encompass AlN compound semiconductor materials which comprise Ga and/or In and/or further elements in the form of impurities, which may be dictated by the process, for example.

It has been found that by adding oxygen to an intermediate layer between the active region and the substrate, said intermediate layer being based on an AlN compound semiconductor material, it is possible to achieve a high crystal quality of the layers of the active region which are grown thereabove and which are grown with a comparatively high thickness, for instance 3 μm or more. In particular, the active region can thereby be grown with high crystalline quality and homogeneity. In particular, the quality and homogeneity can be achieved in a lateral direction, that is to say, perpendicularly to the deposition direction. An increased crystal quality and homogeneity can be ascertained, for example, on the basis of reduced values of full width at half maximum of crystallographic X-ray reflections, for example, by means of measured rocking curves of the (002), (102) and (201) reflections. In comparison with known semiconductor components in which nitridic compound semiconductor materials are grown on silicon substrates, the inventors have been able to ascertain such an improvement in the crystalline quality and homogeneity in the present case for the embodiments and exemplary embodiments described here.

In accordance with a further embodiment, the intermediate layer has an oxygen content that is greater than or equal to 0.1%. Particularly preferably, the oxygen content can be greater than or equal to 1%. Furthermore, the oxygen content of the intermediate layer can be less than or equal to 5% and preferably less than or equal to 3%. Hereinafter, an oxygen content of the intermediate layer measured in percent denotes the proportion of the oxygen atoms in the intermediate layer in atom % relative to the number of atoms of the host crystal of the intermediate layer, that is to say of the Al and N atoms, for example.

It has been found that the lattice constant of the intermediate layer can advantageously be altered by the added oxygen in such a way that the layers of the active region of the semiconductor layer sequence that are grown above the intermediate layer can be deposited with an improved crystalline quality and homogeneity.

In order to produce the intermediate layer, in accordance with a further embodiment, an oxygen-containing compound can be provided during the growth method, said compound being fed to the growth chamber alongside other starting materials for the growth of the semiconductor layer sequence and, in particular, of the intermediate layer. By way of example, a suitably chosen proportion of oxygen gas can be added to a carrier gas provided, for instance, a nitrogen gas. Particularly preferably, in order to produce the intermediate layer, an oxygen-containing metal organyl compound is provided and fed to the growth chamber. Particularly advantageously, diethylaluminum ethoxide (DEAlO) can be provided as the oxygen-containing metal organyl compound in this case. The inventors have found that such a metal organyl compound, in comparison with other oxygen-containing starting materials, enables particularly simple and high-quality production of the intermediate layer and thus also of the further semiconductor layer sequence applied thereabove.

In accordance with a further embodiment, the intermediate layer has a thickness of greater than or equal to 5 nm. Depending on the degree of doping and arrangement of the intermediate layer in the semiconductor layer sequence, the intermediate layer can also have a thickness of greater than or equal to 10 nm, greater than or equal to 15 nm, or even greater than or equal to 20 nm. Furthermore, the intermediate layer can have a thickness of less than or equal to 300 nm, depending on the arrangement and degree of doping also a thickness of less than or equal to 200 nm, less than or equal to 100 nm, less than or equal to 50 nm, less than or equal to 30 nm, or even less than or equal to 20 nm.

In particular, the intermediate layer can be applied as part of an intermediate region on the substrate having the silicon surface. The intermediate region applied as part of the semiconductor layer sequence between the active region and the substrate can have a nucleation or seeding layer, for example, furthermore a transition layer, which is embodied, for example, as a layer sequence in which the Ga content is increased step by step or continuously from layer to layer, and thereabove a strain layer having AN and/or AlGaN intermediate layers, for example, which are overgrown alternately with GaN.

In accordance with a further embodiment, the intermediate layer is embodied as a nucleation layer. In this case, the intermediate layer can be applied in particular as a first layer of the intermediate region, in particular as a first nucleation layer, directly on the substrate, that is to say on the silicon surface of the substrate. In addition, the semiconductor layer sequence can also contain further nucleation layers, which, for example, are also grown from oxygen-doped AN compound semiconductor material. The thickness of the nucleation layer can have one of the abovementioned thicknesses and furthermore preferably be greater than or equal to 50 nm and less than or equal to 300 nm, preferably for example approximately 200 nm.

In accordance with a further embodiment, the intermediate layer is embodied as a transition layer or as part of a transition layer between the active region and the substrate, in particular, between the active region with a nucleation layer. That can, in particular, also mean that the transition layer has a layer sequence having AN and/or AlGaN layers in which the Ga proportion is increased in a direction from the substrate toward the active region, that is to say in the growth direction. In this case, the intermediate layer can be embodied as the layer sequence or else as one or more layers of the layer sequence of the transition layer.

In accordance with a further embodiment, the at least one intermediate layer can be arranged between a transition layer and the active region. That can mean, in particular, that the intermediate layer directly adjoins the active region, that is to say those layers of the semiconductor layer sequence which determine the actual functionality of the semiconductor component. In this case, the intermediate layer can have one of the abovementioned thicknesses and furthermore in particular a thickness of preferably less than or equal to 50 nm, for example, of 20 nm.

### BRIEF DESCRIPTION OF THE DRAWINGS

Further advantages and advantageous embodiments and developments will become apparent from the embodiments described below in conjunction with FIGS. 1 to 4C.

FIG. 1 shows a schematic illustration of a semiconductor component in accordance with one exemplary embodiment;

FIGS. 2 and 3 show schematic illustrations of semiconductor components in accordance with further exemplary embodiments; and

FIGS. 4A to 4C show schematic illustrations of a method for producing a semiconductor component in accordance with a further exemplary embodiment.

### DETAILED DESCRIPTION OF ILLUSTRATIVE EMBODIMENTS

In the exemplary embodiments and figures, identical or identically acting constituent parts may in each case be provided with the same reference signs. The illustrated elements and their size relationships among one another should not be regarded as true to scale, in principle; moreover, individual elements, such as, e.g., layers, structural parts, components and regions, may be illustrated with exaggerated thickness or size dimensions in order to enable better illustration and/or in order to afford a better understanding.

The following exemplary embodiments show purely by way of example semiconductor components embodied as light-emitting diode chips. That means, in particular, that the semiconductor components shown each have an active region suitable for emitting light during operation. As an alternative or in addition thereto, the active region of the semiconductor components shown can also have radiation-receiving layers. Furthermore, the semiconductor components in accordance with the exemplary embodiments can alternatively or additionally also be embodied as electronic semiconductor components, that is to say, for example, as transistors, for instance HEMT or HBT, which have correspondingly embodied active regions.

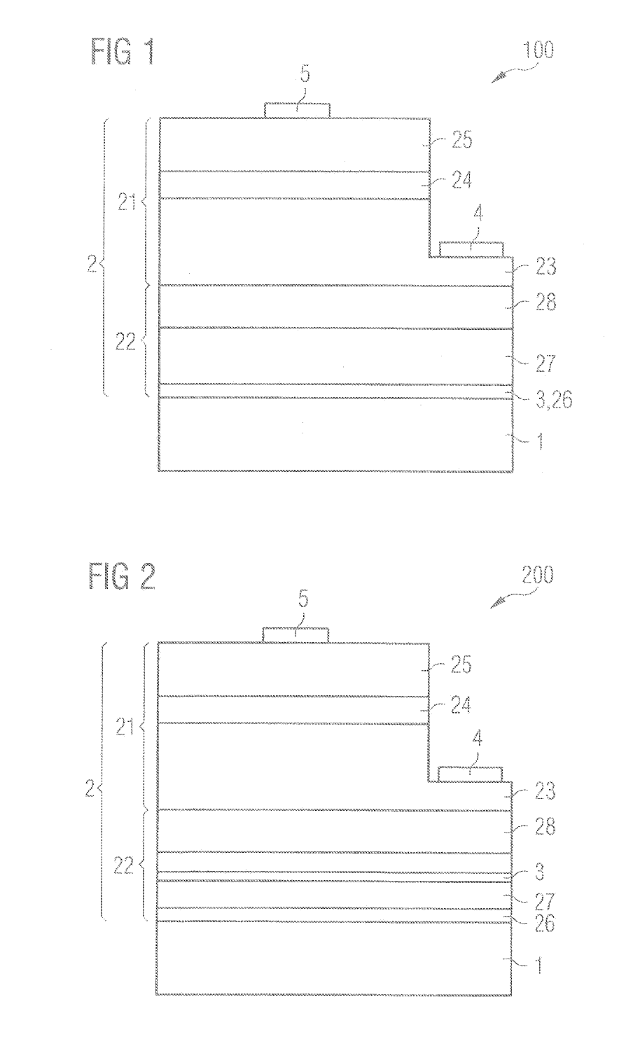

FIG. 1 shows an exemplary embodiment of a semiconductor component 100 comprising a semiconductor layer sequence 2 on a substrate 1. The semiconductor layer sequence is preferably deposited epitaxially, for instance, by means of an metalorganic vapor phase epitaxy (MOVPE) or molecular beam epitaxy (MBE) method, on the substrate 1.

The substrate has a silicon surface facing the semiconductor layer sequence 2, on which silicon surface the semiconductor layer sequence 2 is applied. A bulk silicon substrate, in particular, is suitable as substrate 1. As an alternative thereto, however, it is also possible to use an SOI substrate. Particularly preferably, the substrate 1 has as silicon surface a surface having a (111) orientation. As described in the general part, such a (111) plane of silicon, on account of a hexagonal symmetry, is particularly suitable for the epitaxial growth of nitridic compound semiconductor materials. In comparison with customary growth substrates for nitridic compound semiconductor materials such as, for instance, sapphire, silicon carbide or gallium nitride, a substrate having a silicon surface can be available and producible cost-effectively and with a large area.

The semiconductor layer sequence 2 is based on a nitridic compound semiconductor material, in particular on AlₙGaₘIn₁₋ₘ₋ₙN, where 0≦n≦1, 0≦m≦1 and n+m≦1. The semiconductor layer sequence 2 has an active region 21, which is grown on an intermediate region 22 on the substrate 1.

The active region 21 of the semiconductor layer sequence has an active layer 24 suitable for emitting light during operation of the semiconductor component 100. For this purpose, the active layer 24 is arranged between a first semiconductor layer 23 and a second semiconductor layer 24, which are p- and n-doped, respectively. In this case, the layer construction of the active region 21 is shown purely by way of example and can have further functional layers.

During operation of the semiconductor component, charge carriers can be injected via electrical contacts 4 and 5 from different sides into the active layer 24, and can recombine there with emission of light.

The active region 21 preferably has a thickness of greater than or equal to 2 μm and less than or equal to 8 μm, particularly preferably greater than or equal to 3 μm and less than or equal to 5 μm. In the exemplary embodiment shown, the active region can have in particular a thickness of approximately 4 μm or less and particularly preferably of greater than or equal to 1.5 μm and less than or equal to 2.5 μm. Depending on the type of semiconductor component 100 and the embodiment of the active region 21 of the semiconductor layer sequence 2, however, larger or smaller thicknesses may also be expedient.

With a substrate having a smaller coefficient of thermal expansion than the material to be deposited, as is the case in the following case for the substrate 1 having the silicon surface and the semiconductor layer sequence 2 composed of the nitridic compound semiconductor material, the preferably epitaxial deposition of the nitridic compound semiconductor material is preferably effected in such a way that the semiconductor layer sequence 2 is compressively strained at a deposition temperature relative to the substrate 1. That is to say that the compound semiconductor material assumes a lattice constant which, in the lateral plane, is less than an intrinsic lattice constant of the compound semiconductor material. During the cooling of the semiconductor layer sequence 2 after growth, this reduces the risk that the difference in the coefficients of thermal expansion between the semiconductor layer sequence 2 and the substrate 1 will result in disturbances in the semiconductor layer sequence 2, for example, cracks.

In order to grow the semiconductor layer sequence 2 and in particular the active region 21 in a compressively strained manner, the semiconductor layer sequence 2 has the intermediate region 22 between the active region 21 and the substrate 1, said intermediate region adjoining the substrate 1. The active region 21 is formed on that side of the intermediate region 22 which faces away from the substrate 1.

The semiconductor layers of the intermediate region 22 predominantly serve for increasing the quality of the semiconductor layers 23, 24, 25—shown purely by way of example—of the active region 21, which is crucial for the operation of the semiconductor component 100.

The intermediate region 22 has a nucleation or seeding layer 26, a transition layer 27 and a strain layer 28, which are deposited successively on the substrate 1.

The nucleation layer 26 adjoining the substrate 1 is based on an AN compound semiconductor material and, in the exemplary embodiment shown, is composed of AN, in particular. The nucleation layer 26 serves for seeding the substrate 1 and has a thickness of between 50 nm and 300 nm, for example, 200 nm.

In the exemplary embodiment shown in FIG. 1 for the semiconductor component 100, the nucleation layer 26 is embodied as at least one intermediate layer 3 composed of oxygen-doped AN compound semiconductor material. For this purpose, the nucleation layer is doped with an oxygen content of greater than or equal to 0.1% and less than or equal to 5%, preferably of greater than or equal to 1%. It has been found that the active region 21, which has a thickness of 4 μm, for example, and which is constructed from a GaN-based nitridic compound semiconductor material in the exemplary embodiment shown, can be grown with an improved crystalline quality and homogeneity.

In order to grow the intermediate layer 3, as oxygen-containing compound an oxygen-containing metal organyl compound, in particular diethylaluminum ethoxide (DEAlO), is provided alongside further starting materials. The inventors have discovered that, by means of DEAlO as starting material and for the provision of oxygen, the intermediate layer 3 can be embodied in such a way that the active region 21 can be produced with an improved crystal quality.

The transition layer 27 based on AlGaN, which has a total thickness of approximately 150 nm in the exemplary embodiment shown, is applied on the nucleation layer 26 embodied as at least one intermediate layer 3 composed of an oxygen-doped AN compound semiconductor material. In this case, the transition layer 27 is embodied as a layer sequence having a plurality of layers in which the gallium content is increased step by step or continuously in the growth direction.

The strain layer 28 on the transition layer 27 serves to form a compressive strain at the deposition temperature of the semiconductor layer sequence 2. During cooling after the growth of the semiconductor layer sequence 2, said compressive strain can completely or at least partly compensate for tensile strains caused by the difference in the coefficients of thermal expansion between the substrate 1 and the semiconductor layer sequence 2. For this purpose, the strain layer 28 has one or more GaN layers embedded into one or more AlGaN layers, for example, 2 to 3 AlGaN layers. For this purpose, the AlGaN layers are grown, for example, with a thickness of approximately 20 nm and overgrown with the GaN layers, thus resulting in an alternate sequence of the AlGaN and GaN layers. The thickness of the strain layer 28 is preferably in a range of greater than or equal to 2 μm and less than or equal to 3 μm, for example, 2.5 μm.

The intermediate region 22 is largely independent of the succeeding active region 21 and can therefore also be used for other optoelectronic or electronic components.

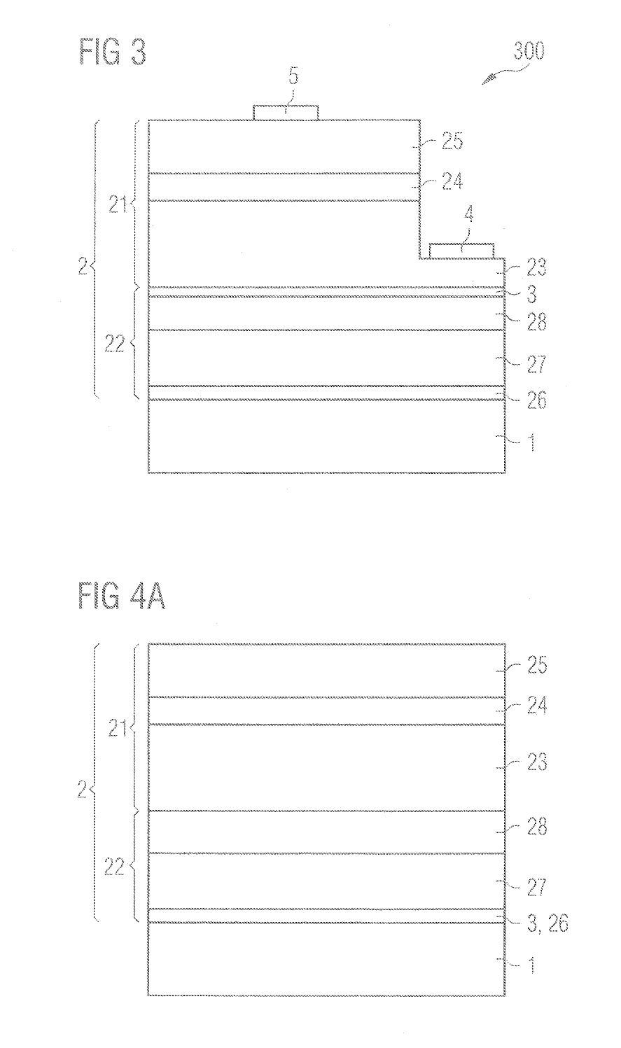

FIG. 2 shows a further exemplary embodiment of a semiconductor component 200.

In comparison with the semiconductor component 100 in accordance with the exemplary embodiment of FIG. 1, the semiconductor component 200 has a transition layer 27 embodied as a layer sequence having at least one intermediate layer 3 composed of an oxygen-doped AN compound semiconductor material, for example, AN or AlGaN. In this case, as illustrated in the exemplary embodiment shown, the intermediate layer 3 can be arranged within the transition layer 27 or else, as an alternative thereto, for example, as a first layer of the transition layer 27 directly on the nucleation layer 26.

Furthermore, it is also possible, for example, for all the layers of the transition layer 27 to be based on an oxygen-doped AN compound semiconductor material and to comprise oxygen-doped AlGaN, for example.

FIG. 3 shows a further exemplary embodiment of a semiconductor component 300, wherein, in comparison with the two previous exemplary embodiments, an intermediate layer 3 composed of an oxygen-doped AN compound semiconductor material is arranged between the active region 21 and the transition layer 27, in particular in a manner directly adjoining the active region 21. In this case, in the exemplary embodiment shown, the intermediate layer 3 has a thickness of just 20 nm. It has been found that the crystal quality of the active region 21 can be significantly improved by means of such an intermediate layer 3 that is applied as the terminating layer of the intermediate region 22.

As an alternative to the exemplary embodiments shown in FIGS. 1 to 3 each having one intermediate layer 3, the semiconductor components 100, 200, 300 shown can in each case also have a plurality of intermediate layers composed of oxygen-doped AN compound semiconductor material. In particular, semiconductor components having combinations of the exemplary embodiments shown are also conceivable.

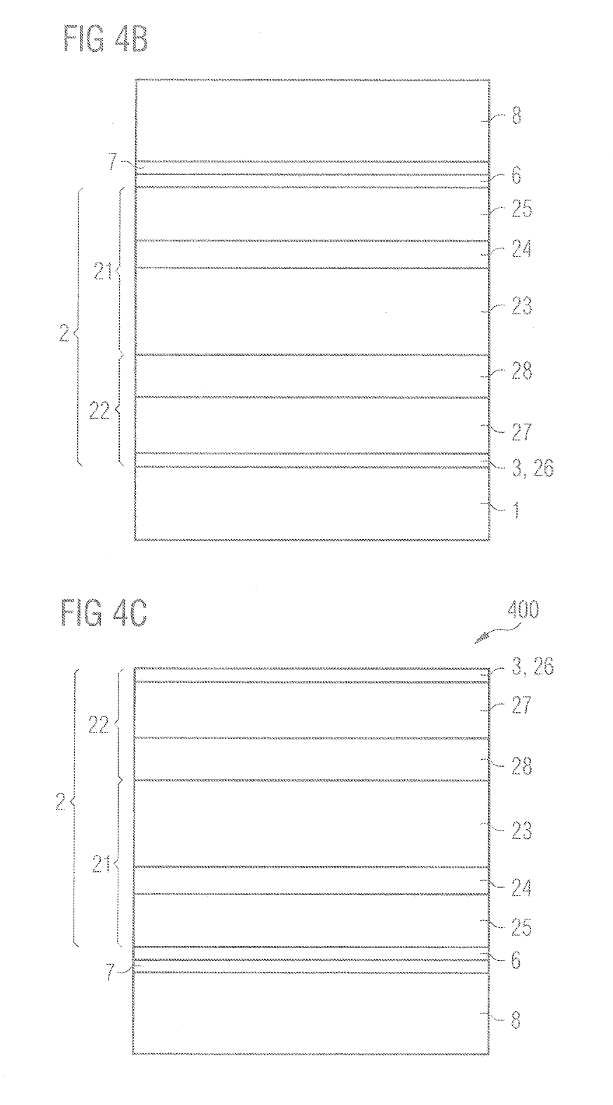

FIGS. 4A to 4C show an exemplary embodiment of a method for producing a semiconductor component 400.

For this purpose, in first method step in accordance with FIG. 4A, a semiconductor layer sequence 2, based on a nitridic compound semiconductor material, is applied on a substrate 1 having a silicon surface. In this case, in the exemplary embodiment shown, the application process is effected by means of epitaxial growth by an MOVPE or MBE method. In the exemplary embodiment shown, the semiconductor layer sequence is embodied with the active region 21 and the intermediate region 22 as in the exemplary embodiment in accordance with FIG. 1. As an alternative thereto, the semiconductor layer sequence 2 can also have features in accordance with the further exemplary embodiments and/or in accordance with the embodiments in the general part.

After the semiconductor layer sequence 2 has been applied, it is processed further in order to produce thin-film semiconductor chips in accordance with the following method steps. As illustrated in FIG. 4B for this purpose a carrier substrate 8 is fixed on the active region 21 by means of a connecting layer 7, for example, a solder or an electrically conductive adhesive layer. In this case, the carrier substrate 8 does not have to have the high crystalline properties of a growth substrate and can for example also be chosen with regard to other suitable properties, for instance, with regard to a high thermal conductivity. By way of example, a semiconductor material such as, for instance, silicon, germanium or gallium arsenide or else a ceramic material such as, for instance, aluminum nitride or boron nitride is suitable for the carrier substrate 8.

Before the carrier substrate 8 is applied by means of the connecting layer 7, a mirror layer 6 is applied on the active region 21. In this case, the minor layer 6 serves to reflect the radiation generated in the active layer 24 during operation of the subsequently completed semiconductor component. The mirror layer 7 particularly preferably comprises a metal having a high reflectivity for the radiation generated in the active layer 24, or a corresponding metallic alloy. In the visible spectral range, in particular aluminum, sliver, rhodium, palladium, nickel and/or chromium or else alloys and/or layer sequences thereof are suitable.

The carrier substrate 8 advantageously serves for mechanically stabilizing the semiconductor layer sequence 2. The substrate 1 having the silicon surface is no longer necessary for this purpose and can be removed, as shown in FIG. 4C, or else thinned. This can be done, for example, wet-chemically, dry-chemically or by a mechanical method such as, for instance, grinding, polishing or lapping. Alternatively or additionally, the thinning or removal of the substrate 1 can also be made possible by the incidence of preferably coherent radiation.

A semiconductor component in which a growth substrate has been thinned or removed is also designated as a thin-film semiconductor component.

By way of example, a light-emitting diode chip can be embodied as a thin-film semiconductor component and can be distinguished, in particular, by at least one of the following characteristic features:
a reflective layer is applied or formed at a first main surface—facing toward the carrier substrate—of a radiation-generating epitaxial layer sequence, said reflective layer reflecting at least part of the electromagnetic radiation generated in the epitaxial layer sequence back into the latter;
the epitaxial layer sequence has a thickness in the range of 20 μm or less, in particular in the range of 10 μm or less; and
the epitaxial layer sequence contains at least one semiconductor layer having at least one area having an intermixing structure which ideally leads to an approximately ergodic distribution of the light in the epitaxial layer sequence, that is to say that it has an as far as possible ergodic stochastic scattering behavior.

A basic principle of a thin-film light-emitting diode chip is described, for example, in I. Schnitzer, et al., Applied Physics Letters 63 (16), Oct. 18, 1993, pages 2174-2176, the disclosure content of which in this respect is hereby incorporated by reference.

After the removal or thinning of the substrate 1, that surface of the semiconductor layer sequence 2 which faces away from the carrier substrate 8 can, for example, also be provided with a structuring, for example a roughening (not shown). The coupling-out efficiency for the radiation generated in the active layer 24 can thus be increased. The roughening or the structuring can in this case extend into the intermediate region 22 in such a way that the latter is at least partly removed. By way of example, the nucleation layer 26 and the transition layer 27 can be partly or even completely removed, such that the structuring can be formed in the strain layer 28.

For the injection of charge carriers into the active layer 24, it is furthermore possible also to apply contacts, for instance, by means of vapor deposition or sputtering (not shown).

The carrier substrate 8 with the active region 21 can furthermore be singulated into individual semiconductor components 400.

Furthermore, it may also be possible that, before the carrier substrate 8 is applied, contact structures are introduced into the semiconductor layer sequence 2, in particular into the active region 21, said contact structures making it possible to make contact with the active layer on both sides in the subsequently completed semiconductor component 400, wherein electrical contacts need only be arranged on one side of the active region 21.

The semiconductor components described here, in which a semiconductor layer sequence 2 is grown on a silicon surface of a substrate 1, are distinguished by an improved crystal quality of the active region 21, which can be demonstrated, in particular, for example, by reduced values of full width at half maximum crystallographic X-ray reflections, measured as so-called rocking curves, for example, of the (002), (102) and (201) reflections.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or the exemplary embodiments.

1-15. (canceled)

16. A semiconductor component comprising:
a semiconductor layer sequence composed of a nitridic compound semiconductor material on a substrate,
wherein the substrate has a silicon surface facing the semiconductor layer sequence; and
wherein the semiconductor layer sequence has an active region and an intermediate layer composed of an oxygen-doped AN compound semiconductor material between the substrate and the active region.

17. The semiconductor component according to claim 16, wherein the oxygen content of the intermediate layer is greater than or equal to 0.1% and less than or equal to 5%.

18. The semiconductor component according to claim 16, wherein the intermediate layer has a thickness of greater than or equal to 5 nm and less than or equal to 300 nm.

19. The semiconductor component according to claim 16, wherein the intermediate layer comprises a nucleation layer applied directly on the substrate.

20. The semiconductor component according to claim 16, wherein the intermediate layer comprises a transition layer or part of a transition layer between the active region and a nucleation layer.

21. The semiconductor component according to claim 20, wherein a plurality of intermediate layers are arranged between the active region and the nucleation layer as the transition layer or part of the transition layer.

22. The semiconductor component according to claim 16, wherein the intermediate layer is arranged between a transition layer and the active region.

23. The semiconductor component according to claim 22, wherein the intermediate layer has a thickness of 20 nm.

24. The semiconductor component according to claim 16, wherein the intermediate layer directly adjoins the active region.

25. The semiconductor component according to claim 24, wherein the intermediate layer has a thickness of 20 nm.

26. The semiconductor component according to claim 16, wherein the silicon surface is a (111) plane.

27. The semiconductor component according to claim 16, wherein the substrate comprises a silicon bulk substrate.

28. The semiconductor component according to claim 16, wherein the nitridic compound semiconductor material comprises AlₙGaₘIn₁₋ₘ₋ₙN, where 0≦n≦1, 0≦m≦1 and n+m≦1.

29. A method for producing a semiconductor component, the method comprising:
applying a semiconductor layer sequence composed of a nitridic compound semiconductor material to a substrate;
wherein the substrate has a silicon surface facing the semiconductor layer sequence; and
wherein the semiconductor layer sequence has an active region and an intermediate layer composed of an oxygen-doped AN compound semiconductor material between the substrate and the active region.

30. The method according to claim 29, wherein an oxygen-containing metal organyl compound is provided for producing the intermediate layer.

31. The method according to claim 30, wherein the oxygen-containing metal organyl compound is diethylaluminum ethoxide.

32. The method according to claim 29, further comprising removing or thinning the substrate at least in regions after the semiconductor layer sequence has been applied.

33. A semiconductor component comprising:
a semiconductor layer sequence composed of a nitridic compound semiconductor material on a substrate;
wherein the substrate has a silicon surface facing the semiconductor layer sequence;
wherein the semiconductor layer sequence has an active region and an intermediate layer composed of an oxygen-doped AN compound semiconductor material between the substrate and the active region; and
wherein the intermediate layer is a transition layer or part of a transition layer between the active region and a nucleation layer or is arranged between a transition layer and the active region.
